(19) United States
(12) Patent Application Publication
(10) Pub. No.: US 2024/0407149 A1
(43) Pub. Date: Dec. 5, 2024

(54) COMPONENT MOUNTING DEVICE

(71) Applicant: FUJI CORPORATION, Chiryu (JP)

(72) Inventors: Chikashi TESHIMA, Okazaki-shi (JP); Takayuki MIZUNO, Okazaki-shi (JP)

(73) Assignee: FUJI CORPORATION, Chiryu (JP)

(21) Appl. No.: 18/698,548

(22) PCT Filed: Oct. 25, 2021
(86) PCT No.: PCT/JP2021/039344

§ 371 Date: Apr. 4, 2024

(51) Int. Cl. H05K 13/04

(52) U.S. Cl. CPC H05K 13/0409; H05K 13/041

(57) ABSTRACT

A component mounting device includes a suction nozzle supplied with negative pressure air to perform pickup operation of a component, and is blocked from the negative pressure air to perform mounting operation of the component on a board, a first negative pressure supply section to supply the negative pressure air when the suction nozzle starts the pickup operation to when the suction nozzle starts the mounting operation, a second negative pressure supply section to supply the negative pressure air, a negative pressure detection section, and a negative pressure supply control section to operate the second negative pressure supply section when the detected pressure value of the negative pressure air is closer to an atmospheric pressure value than a predetermined value set between the atmospheric pressure value and a vacuum value.

### TECHNICAL FIELD

The present description relates to a component mounting device including a suction nozzle to which negative pressure air is supplied to pick up a component.

### BACKGROUND ART

A technique of mass-producing board products by performing board work on a board on which printed wiring is performed has become widespread. A typical example of a board work machine that performs the board work is a component mounting device that performs component mounting work. Many component mounting devices include a suction nozzle to which negative pressure air is supplied and which picks up a component, a negative pressure supply section which supplies the negative pressure air to the suction nozzle, and a drive mechanism which moves the suction nozzle up and down and horizontally. The suction nozzle that has picked up a component is driven by the drive mechanism to move above a board, and is blocked from the negative pressure air to mount the component on the board. An example of a technique relating to this type of component mounting device is disclosed in Patent Literature 1.

A head for a component mounting device disclosed in Patent Literature 1 includes a vacuum pressure supply section that supplies vacuum pressure to an airtight chamber to which multiple suction nozzles are attached, and an ejector that supplies negative pressure to any of the determined suction nozzles via a hollow shaft. Accordingly, even if the number of the suction nozzles increases, it is possible to suppress an increase in the number of the ejectors for generating the vacuum pressure and an increase in the amount of the compressed air to be supplied.

### Patent Literature

Patent Literature 1: JP-A-2008-171915

### SUMMARY OF THE INVENTION

### Technical Problem

Here, many component mounting devices include a mounting head having multiple suction nozzles, and an air flow path communicating with multiple suction nozzles from a negative pressure supply section has a branch structure. In the pickup operation of a component, if a pickup failure occurs when the component cannot be picked up by a sharp suction nozzle, the amount of leakage of the negative pressure air becomes large, and the negative pressure in the nozzle decreases. The decrease in negative pressure also affects other suction nozzles via the air flow path.

In the present description, “negative pressure air” refers to air whose pressure value is smaller than an atmospheric pressure value and whose gauge pressure is a negative pressure value (negative pressure). The “leakage of negative pressure air” indicates a phenomenon in which air flows into the negative pressure suction nozzle from the atmosphere side. The “decrease in negative pressure” indicates that the pressure value changes from the vacuum value side to the atmospheric pressure value side (increase in absolute pressure) due to leakage of the negative pressure air. When the decrease in the negative pressure in the suction nozzle becomes remarkable, the holding force for picking up and holding the component decreases, and the component falls.

In addition, also when the suction nozzle picks up a component in an inclined posture or when the surface of the component to be picked up has unevenness, leakage of the negative pressure air similarly occurs, and the negative pressure in all the suction nozzles decreases. As a countermeasure for this, the configuration of Patent Literature 1 cannot be adopted because the configuration does not include a branch structure of the air flow path. In the conventional countermeasure technique, when the pressure value of the negative pressure air becomes lower than a threshold pressure value, the subsequent pickup operation is stopped and the mounting operation of the picked-up component is performed. Accordingly, it is possible to end the mounting operation before the decrease in negative pressure becomes remarkable and to avoid falling of a component. However, in this countermeasure technique, the number of components to be mounted decreases, and the work efficiency of the mounting work decreases.

Further, in recent years, there has been a tendency to increase the moving speed of a suction nozzle in order to increase the efficiency for retuning. In this case, it is important to ensure a large component holding force by maintaining a good negative pressure in the suction nozzle and prevent a component from falling by an inertial force generated by a change in the moving speed. In addition, if the component holding force of the suction nozzle can be increased, it is possible to pick up, convey, and mount a component heavier than in the related art.

Therefore, an object of the present description is to provide a component mounting device capable of suppressing a decrease in negative pressure in a suction nozzle that picks up a component.

### Solution to Problem

According to an aspect of the present description, a component mounting device includes a suction nozzle configured to be supplied with negative pressure air to perform pickup operation of picking up a component, and configured to be blocked from the negative pressure air to perform mounting operation of mounting the component on a board, a first negative pressure supply section configured to supply the negative pressure air to the suction nozzle throughout a time band from when the suction nozzle starts the pickup operation to when the suction nozzle starts the mounting operation, a second negative pressure supply section configured to supply the negative pressure air to the suction nozzle, a negative pressure detection section configured to directly or indirectly detect a pressure value of the negative pressure air supplied to the suction nozzle, and a negative pressure supply control section configured to operate the second negative pressure supply section when the detected pressure value of the negative pressure air is closer to an atmospheric pressure value than a predetermined value set between the atmospheric pressure value and a vacuum value.

### Advantageous Effect of the Invention

In the component mounting device disclosed in the present description, the first negative pressure supply section operates at least throughout the time band from when the suction nozzle starts the pickup operation to when the suction nozzle starts the mounting operation, and maintains the inside of the suction nozzle at a negative pressure. Here, when the suction nozzle cannot pick up a component, or when the posture of the component or the state of the surface to be picked up is not good even when the suction nozzle can pick up the component, the negative pressure air leaks, and the negative pressure decreases in the suction nozzle. In addition, in a configuration including multiple suction nozzles, when a decrease in negative pressure occurs in the suction nozzle, the decrease in negative pressure affects other suction nozzles in communication. When the negative pressure decreases in this manner, the negative pressure detection section detects the decrease in the negative pressure, and the negative pressure supply control section operates the second negative pressure supply section, and therefore the decrease in the negative pressure inside the suction nozzle can be suppressed by operating the first negative pressure supply section and the second negative pressure supply section in parallel.

### BRIEF DESCRIPTION OF DRAWINGS

FIG. 1 is a plan view illustrating an overall configuration of a component mounting device according to a first embodiment.

FIG. 2 is a view schematically illustrating an air supply system that selectively supplies negative pressure air and positive pressure air to a suction nozzle.

FIG. 3 is a view illustrating three states classified by a predetermined value and a threshold pressure value used for determining the pressure value of the negative pressure air, and the pressure value of the negative pressure air.

FIG. 4 is a view of an operation flow when the component mounting device performs the pickup and mounting cycle by using the suction nozzle.

FIG. 5 is a time chart schematically illustrating an operation of an ejector (second negative pressure supply section) when the suction nozzle can pick up a component properly in an operation flow.

FIG. 6 is a time chart schematically illustrating the operation of the ejector (second negative pressure supply section) when the suction nozzle cannot pick up a component properly and the negative pressure air leaks in an operation flow.

FIG. 7 is a view of an operation flow when pickup operation using the suction nozzle is performed, and is a view of an operation flow modified from FIG. 4.

FIG. 8 is a view schematically illustrating an air supply system according to a second embodiment.

FIG. 9 is a view schematically illustrating an air supply system according to a third embodiment.

### DESCRIPTION OF EMBODIMENTS

### 1. Overall Configuration of Component Mounting Device 1 According to First Embodiment

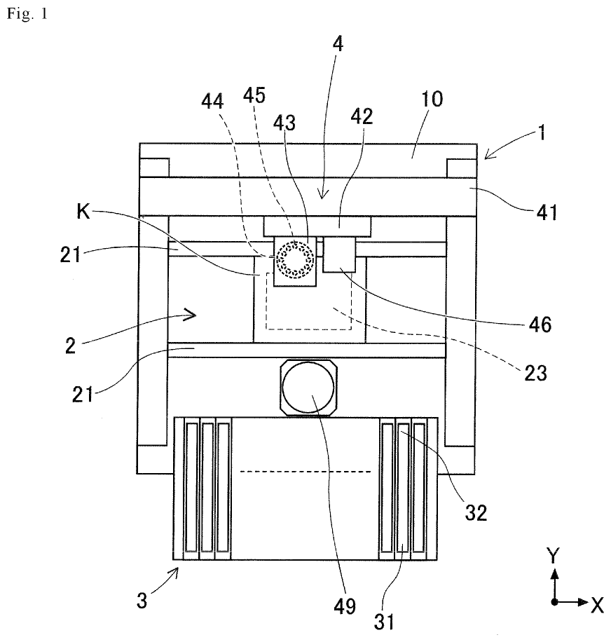

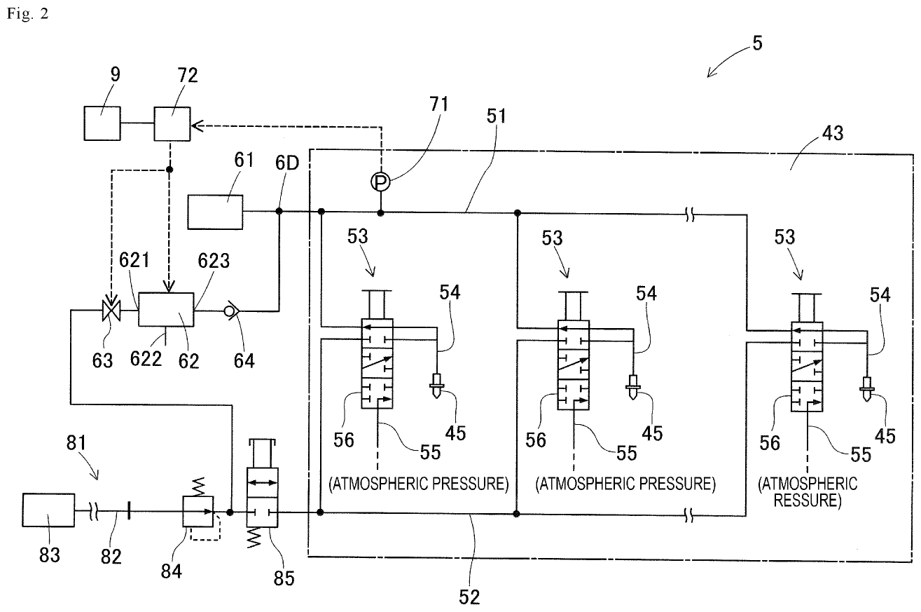

An overall configuration of component mounting device 1 of a first embodiment will be described with reference to FIG. 1. Component mounting device 1 performs mounting work for mounting a component on board K. A direction from the left toward the right on the drawing surface in FIG. 1 in which board K is conveyed is an X axis direction, and a direction from the bottom (front side) toward the top (rear side) on the drawing surface is a Y axis direction. Component mounting device 1 is configured by assembling board conveyance device 2, component supply device 3, component transfer device 4, mounting control section 9 (see FIG. 2), and the like to base 10.

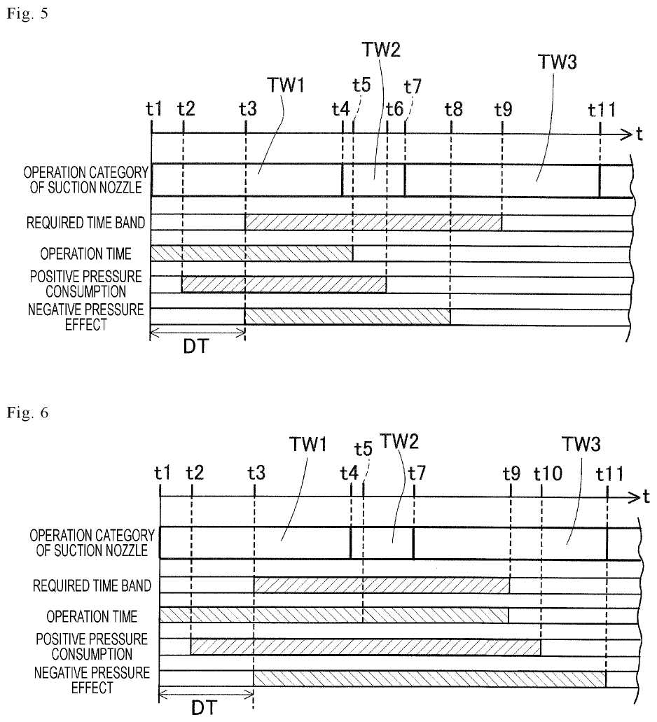

Board conveyance device 2 includes a pair of guide rails 21, a pair of conveyance belts (not illustrated), clamp mechanism 23, and the like. The pair of guide rails 21 extends in the conveyance direction (X axis direction) across the center of the upper surface of base 10, and is assembled to base 10 in parallel with each other. The pair of conveyance belts rotate along guide rails 21 in a state in which two parallel sides of board K are placed, and carry in board K to a work performing position in the vicinity of the center of base 10. Clamp mechanism 23 pushes up carried board K and clamps board K between pressing portions 22 (see FIG. 5) of guide rails 21 to position board K. After the mounting work of a component by component transfer device 4 ends, clamp mechanism 23 releases board K, and the conveyance belts carry out board K to the outside of the device.

Component supply device 3 includes multiple tape feeders 31 arranged in the X axis direction. Each tape feeder 31 feeds a carrier tape in which multiple components are housed in a row toward supply position 32 on a front end side. The carrier tape supplies the component such that the component can be collected at supply position 32.

Component transfer device 4 includes Y-axis moving body 41, X-axis moving body 42, mounting head 43, rotary tool 44, multiple suction nozzles 45, board recognition camera 46, component recognition camera 49, and the like. Y-axis moving body 41 is formed of a member elongated in the X axis direction, and is driven by a Y-direction drive mechanism to move in the Y axis direction. X-axis moving body 42 is mounted on Y-axis moving body 41, and is driven by an X-direction drive mechanism to move in the X axis direction. Mounting head 43 is attached to a clamp mechanism (not illustrated) provided on a front face of X-axis moving body 42, and moves in two horizontal directions together with X-axis moving body 42.

Rotary tool 44 is rotatably provided below mounting head 43. Rotary tool 44 is driven by an R-axis drive mechanism (not illustrated) to rotate about a vertical central axis. Rotary tool 44 includes multiple (twelve in the example of FIG. 1) suction nozzles 45 at equal distances from the vertical central axis. Suction nozzle 45 is driven by a lifting and lowering drive mechanism (not illustrated) to move up and down, and is driven by a θ-axis drive mechanism (not illustrated) to rotate about a vertical axis. When rotary tool 44 rotates, suction nozzle 45 revolves around the vertical central axis of rotary tool 44. Suction nozzle 45 is selectively supplied with negative pressure air and positive pressure air from air supply system 5 described later. Accordingly, suction nozzle 45 performs pickup operation of picking up a component from component supply device 3 and a mounting operation of mounting the component on board K.

In addition, mounting head 43 may be in a form of holding suction nozzle 45 so as to move up and down, and various modifications are possible. For example, rotary tool 44 may be omitted, and multiple suction nozzles 45 may be directly provided on the lower side of mounting head 43. Further, multiple suction nozzles 45 provided on the lower side of mounting head 43 may be arranged in a line or may be arranged in a grid pattern.

Board recognition camera 46 is provided on X-axis moving body 42 alongside mounting head 43. Board recognition camera 46 is disposed such that an optical axis is directed downward, and images a position reference mark attached to board K from above. The acquired image data is subjected to image processing so that the work performing position of board K is accurately obtained. Examples of board recognition camera 46 include a digital imaging device having an imaging element such as a charge coupled device (CCD) or a complementary metal oxide semiconductor (CMOS).

Component recognition camera 49 is provided on base 10 between board conveyance device 2 and component supply device 3. Component recognition camera 49 is disposed such that an optical axis is directed upward. Component recognition camera 49 images the component held by suction nozzle 45 from the bottom side and recognizes the component while mounting head 43 moves from component supply device 3 to board K. As a result, it is determined whether the type of the component is correct or incorrect, and the position and orientation of the component with respect to suction nozzle 45 are detected and reflected in the mounting work. Examples of component recognition camera 49 include a digital imaging device having an imaging element such as a CCD or a CMOS.

Component transfer device 4 can repeat multiple pickup and mounting cycles for board K whose position is determined. In a pickup and mounting cycle, first, mounting head 43 moves above component supply device 3, and each suction nozzle 45 performs a pickup operation. Next, mounting head 43 moves above component recognition camera 49, and component recognition camera 49 performs imaging. Next, mounting head 43 moves above board K, and suction nozzles 45 perform a mounting operation. Then, mounting head 43 moves toward component supply device 3 again. The pickup and mounting cycle is a generic term of the above-described series of operations.

Mounting control section 9 is assembled to base 10, and a disposition position thereof is not particularly limited. Mounting control section 9 is implemented by a computer device having CPU and operating in software. Mounting control section 9 may be configured such that multiple CPUs are distributed and disposed in the device and connected in communication with each other. Mounting control section 9 controls board conveyance device 2, component supply device 3, and component transfer device 4 based on the mounting work data created for each type of board K. The mounting work data is data describing a detailed procedure of the mounting work, a method of performing the mounting work, or the like. Further, mounting control section 9 controls the operations of multiple suction nozzles 45 and mounting head 43 to advance the pickup operation and the mounting operation of a component.

### 2. Air Supply System 5

Next, air supply system 5 will be described with reference to FIG. 2. Air supply system 5 selectively supplies negative pressure air and positive pressure air to each of suction nozzles 45, and can open the inside of suction nozzle 45 to the atmosphere. The components of air supply system 5 are assembled separately into base 10 and component transfer device 4. Air supply system 5 includes negative pressure air flow path 51, positive pressure air flow path 52, multiple sets of valve devices 53 and nozzle side air flow paths 54 corresponding to suction nozzles 45, first negative pressure supply section 61, ejector 62 corresponding to a second negative pressure supply section, negative pressure detection section 71, negative pressure supply control section 72, positive pressure supply section 81, and the like.

Negative pressure air flow path 51 extends from base 10 to rotary tool 44 via mounting head 43. A first end side of negative pressure air flow path 51 branches into two systems at branch position 6D and communicates with first negative pressure supply section 61 and ejector 62 in parallel. Branch position 6D is provided at a position close to mounting head 43 or inside mounting head 43 even outside mounting head 43. Accordingly, as compared with a configuration in which branch position 6D is provided in the vicinity of first negative pressure supply section 61 and ejector 62, the flow path cross-sectional area when first negative pressure supply section 61 and ejector 62 operate in parallel is equivalently increased. As a result, the supply efficiency of supplying the negative pressure air to suction nozzle 45 is enhanced.

A second end side of negative pressure air flow path 51 branches into the number of systems equal to the number of suction nozzles 45, and each of the systems communicates with valve device 53. The negative pressure air is supplied to negative pressure air flow path 51 from first negative pressure supply section 61 and ejector 62. Actually, in negative pressure air flow path 51, the internal air is sucked by first negative pressure supply section 61 and ejector 62, and the internal pressure value becomes a negative pressure smaller than the atmospheric pressure value.

First negative pressure supply section 61 is provided in base 10. First negative pressure supply section 61 operates through a time band from at least multiple suction nozzles 45 starts the pickup operation to when the suction nozzles 45 start the mounting operation. In the first embodiment, first negative pressure supply section 61 is automatically powered on and continues to operate when component mounting device 1 is in operation. Then, first negative pressure supply section 61 continues to supply the negative pressure air to negative pressure air flow path 51. First negative pressure supply section 61 may be controlled by negative pressure supply control section 72 and operate intermittently for the above-described time band.

Negative pressure air flow path 51 to which the negative pressure air is supplied has an internal pressure value close to a vacuum value, and the negative pressure air can be supplied to suction nozzle 45. Further, suction nozzle 45 performs the pickup operation when the internal pressure value becomes a value close to the vacuum value. First negative pressure supply section 61 is a main element for supplying negative pressure air to suction nozzle 45, and can be referred to as a main negative pressure supply section. For example, an air pump (vacuum pump) can be used as first negative pressure supply section 61. First negative pressure supply section 61 may include a negative pressure air supply path that supplies negative pressure air from a negative pressure source disposed outside the device to the device.

In the first embodiment, ejector 62 is used as the second negative pressure supply section. Ejector 62 is provided on base 10 and controlled by negative pressure supply control section 72. Ejector 62 supplies negative pressure air to negative pressure air flow path 51. Accordingly, ejector 62 can supply the negative pressure air to suction nozzle 45. Ejector 62 is an element that operates in an auxiliary manner when the negative pressure air supplied from first negative pressure supply section 61 is insufficient, and can be referred to as an auxiliary negative pressure supply section.

Opening/closing valve 63 and check valve 64 are attached to ejector 62. Ejector 62 includes positive pressure introduction section 621, positive pressure discharge section 622, and negative pressure generation section 623. Positive pressure introduction section 621 communicates with positive pressure supply section 81 via opening/closing valve 63. The opening/closing operation of opening/closing valve 63 is controlled by negative pressure supply control section 72. Positive pressure discharge section 622 is opened to the atmosphere. Negative pressure generation section 623 communicates with negative pressure air flow path 51 via check valve 64. Check valve 64 (no-return valve) allows the air to flow from negative pressure air flow path 51 toward ejector 62, and blocks the air flow in the reverse direction.

When the positive pressure air is introduced into positive pressure introduction section 621, ejector 62 generates negative pressure air in negative pressure generation section 623 while discharging the positive pressure air to positive pressure discharge section 622. Ejector 62 has response delay time DT (see FIG. 5). Specifically, the time at which the positive pressure air is introduced into positive pressure introduction section 621 is delayed with respect to the time at which negative pressure supply control section 72 instructs opening/closing valve 63 to perform opening operation. In addition, the time at which the negative pressure air generated in negative pressure generation section 623 is supplied to suction nozzle 45 via negative pressure air flow path 51 is further delayed. As ejector 62, a known configuration, for example, a configuration disclosed in Patent Literature 1 can be used.

Positive pressure air flow path 52 extends from base 10 to rotary tool 44 via mounting head 43. A first end side of positive pressure air flow path 52 communicates with positive pressure supply section 81 via positive pressure valve 85. Positive pressure valve 85 is a solenoid valve and is excited to be in an open state and is not excited to be in a closed state. A second end side of positive pressure air flow path 52 branches into the number of systems equal to the number of suction nozzles 45, and each of the systems communicates with valve device 53. The positive pressure air supplied from positive pressure supply section 81 flows through positive pressure air flow path 52.

Positive pressure supply section 81 includes positive pressure air supply path 82 and regulator valve 84. Positive pressure air supply path 82 supplies the positive pressure air to regulator valve 84 from positive pressure source 83 disposed outside component mounting device 1. Positive pressure source 83 is provided to multiple component mounting devices 1 in common, and is commonly provided to a large number of devices in the factory in common. As positive pressure source 83, for example, a compressor (compression pump) or an accumulator tank in which positive pressure air is accumulated by the compressor can be used.

Regulator valve 84 is provided in base 10. Regulator valve 84 reduces the pressure of the positive pressure air to a specified positive pressure value, and discharges and supplies the positive pressure air having a stable positive pressure value. A first branch of positive pressure supply section 81 on the discharge side of regulator valve 84 communicates with opening/closing valve 63 of ejector 62. Positive pressure supply section 81 contributes to generation of negative pressure air and serves as a part of the second negative pressure supply section. Further, a second branch of positive pressure supply section 81 on the discharge side of regulator valve 84 communicates with positive pressure valve 85, and supplies the positive pressure air to suction nozzle 45 via positive pressure air flow path 52. Positive pressure supply section 81 may be a positive pressure source provided inside component mounting device 1.

Valve device 53 is provided in rotary tool 44 so as to correspond to each of suction nozzles 45. Valve device 53 communicates with negative pressure air flow path 51, positive pressure air flow path 52, nozzle side air flow path 54, and atmospheric air flow path 55. Nozzle side air flow path 54 communicates valve device 53 and suction nozzle 45. Atmospheric air flow path 55 opens valve device 53 to the atmosphere.

Valve device 53 is automatically operated in conjunction with the lifting and lowering operation of suction nozzle 45. Valve device 53 may be controlled by negative pressure supply control section 72. Valve device 53 causes any one of negative pressure air flow path 51, positive pressure air flow path 52, and atmospheric air flow path 55 to selectively communicate with nozzle side air flow path 54. As valve device 53, for example, switching valve 56 capable of switching among three types of communication states may be used. Valve device 53 may include multiple valves as long as valve device 53 has the above-described switching function. Further, as a valve constituting valve device 53, fluid valves having various structures can be adopted. The applicant of the present application discloses a detailed configuration example of valve device 53 in WO 2019/026160.

As illustrated in FIG. 2, when nozzle side air flow path 54 is in communication with negative pressure air flow path 51, suction nozzle 45 is supplied with negative pressure air to enter a negative pressure state, and the pickup operation is enabled. When nozzle side air flow path 54 is in communication with positive pressure air flow path 52, suction nozzle 45 is blocked from the negative pressure air and supplied with positive pressure air to enter a positive pressure state, and the mounting operation is enabled. When nozzle side air flow path 54 communicates with atmospheric air flow path 55, suction nozzle 45 is blocked from the negative pressure air and the positive pressure air and is open to the atmosphere to enter an atmosphere open state. Accordingly, the negative pressure air and the positive pressure air do not leak from suction nozzle 45, and waste thereof is prevented.

Negative pressure detection section 71 is provided in mounting head 43. Negative pressure detection section 71 directly or indirectly detects the pressure value of the negative pressure air supplied to suction nozzle 45. As negative pressure detection section 71, a pressure sensor communicating with negative pressure air flow path 51 can be used. Negative pressure detection section 71 outputs the detected pressure value of the negative pressure air to negative pressure supply control section 72.

Negative pressure detection section 71 is not limited to the pressure sensor. For example, negative pressure detection section 71 may include one or more pressure relays that output an ON signal at a set pressure value. Accordingly, this can simplify the determination processing of negative pressure supply control section 72. Further, negative pressure detection section 71 may be configured to detect the flow rate of the negative pressure air by using a flow rate sensor and estimate the pressure value based on the amount of the flow rate.

Negative pressure supply control section 72 is provided in base 10, but the position thereof is not limited. Negative pressure supply control section 72 is implemented by the same computer device as mounting control section 9 or a separate computer device. Negative pressure supply control section 72 controls ejector 62 based on the pressure value of the negative pressure air detected by negative pressure detection section 71. Negative pressure supply control section 72 may control not only ejector 62 but also the entire operation related to the supply of the negative pressure air and the positive pressure air. That is, negative pressure supply control section 72 may control first negative pressure supply section 61, positive pressure valve 85, and multiple valve devices 53 in addition to ejector 62 and opening/closing valve 63.

### 3. Control of Negative Pressure Supply Control Section 72 Based on Pressure Value of Negative Pressure Air

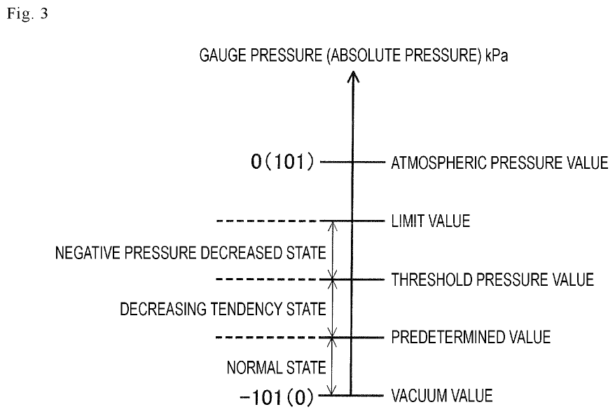

Here, the control performed by negative pressure supply control section 72 based on the pressure value of the negative pressure air will be described with reference to FIG. 3. The negative pressure air in negative pressure air flow path 51 has a pressure value between the atmospheric pressure value and the vacuum value, and has a pressure value within a range of 0 to −101 kPa in gauge pressure notation and a pressure value within a range of 101 to 0 kPa in absolute pressure notation. When each of multiple suction nozzles 45 has successfully picked up a component, the negative pressure air hardly leaks, and at this time, the negative pressure air in negative pressure air flow path 51 and each suction nozzle 45 is maintained at a pressure value close to the vacuum value. In this case, it is sufficient that first negative pressure supply section 61 is operating, and the operation of ejector 62 is not necessary.

However, when one or more suction nozzles 45 cannot pick up a component, or when there is a gap between suction nozzles 45 and the component even if suction nozzles 45 can pick up the component, negative pressure air leaks. Accordingly, a decrease in negative pressure (an increase in absolute pressure) occurs in suction nozzle 45, and the decrease in negative pressure further affects negative pressure air flow path 51 and other suction nozzles 45. In order to deal with a decrease in negative pressure, in the first embodiment, ejector 62 and negative pressure supply control section 72 are provided to operate first negative pressure supply section 61 and ejector 62 in parallel. Further, a predetermined value and a threshold pressure value are set for determination when negative pressure supply control section 72 performs control. The predetermined value and the threshold pressure value are set based on a limit value at which suction nozzle 45 can stably pick up and convey a component.

The limit value represents a pressure value of a minimum condition that a component does not fall when suction nozzle 45 moves while picking up the component. Specifically, when the pressure value of the negative pressure air exceeds the limit value and approaches the atmospheric pressure value, the component holding force with which suction nozzle 45 picks up and holds the component is significantly reduced. This increases the possibility that the picked-up component falls from suction nozzle 45 due to an inertial force acting on the component when suction nozzle 45 moves up and down, rotary tool 44 rotates, or mounting head 43 moves horizontally. Conversely, when the pressure value of the negative pressure air is closer to the vacuum value than the limit value, the component hardly falls.

For this limit value, a predetermined value and a threshold pressure value are set in consideration of a further decrease in negative pressure that may occur before the suction nozzle ends the mounting operation, a predetermined safety factor, and the like. The predetermined value is a determination value for determining whether to cause first negative pressure supply section 61 to operate ejector 62 in parallel. The threshold pressure value is a determination value for determining whether it is not sufficient even if ejector 62 is operated in parallel. The threshold pressure value is set between the limit value and the predetermined value. A case where the pressure value of the negative pressure air is between the limit value and the threshold pressure value is referred to as a negative pressure decreased state. Suction nozzle 45 in a negative pressure decreased state is required to end the mounting operation of a component in a short time before the pressure value changes to the limit value (the absolute pressure increases).

A case where the pressure value of the negative pressure air is between the threshold pressure value and the predetermined value is referred to as a decreasing tendency state. When suction nozzle 45 is in a decreasing tendency state, the negative pressure may continue to decrease. Negative pressure supply control section 72 causes ejector 62 to operate in parallel during the operation of first negative pressure supply section 61. Accordingly, in many cases, suction nozzle 45 is improved from the decreasing tendency state to a normal state (described later), and in other cases, the decreasing tendency state is maintained and the shift to the negative pressure decreased state is prevented.

A case where the pressure value of the negative pressure air is between the predetermined value and the vacuum value is referred to as a normal state. When suction nozzle 45 is in a normal state, there is little risk of a decrease in negative pressure. Negative pressure supply control section 72 determines that it is not necessary to operate ejector 62 in parallel.

As the predetermined value, for example, −75 kPa (gauge pressure) can be used. For example, −55 kPa (gauge pressure) can be used as the threshold pressure value. However, the limit value varies depending on the shape and the opening area of the opening portion or the like of suction nozzle 45, the mass of the component to be picked up and the state of the surface to be picked up, the acceleration and the deceleration when suction nozzle 45 moves, and the like. Therefore, the predetermined value and the threshold pressure value are preferably set based on the limit value.

The control of negative pressure supply control section 72 will be described. Negative pressure supply control section 72 operates ejector 62 when the pressure value of the negative pressure air detected by negative pressure detection section 71 is closer to the atmospheric pressure value than the predetermined value (decreasing tendency state). However, as described above, in ejector 62, response delay time DT elapses from the start of the operation to the supply of the negative pressure air to suction nozzle 45. Therefore, even if negative pressure supply control section 72 receives the detection result of negative pressure detection section 71 and determines the decreasing tendency state, and then operates ejector 62, the negative pressure continues to decrease due to response delay time DT, and the negative pressure is sometimes not in time.

As a countermeasure, negative pressure supply control section 72 performs control in consideration of response delay time DT of ejector 62. Specifically, negative pressure supply control section 72 operates ejector 62 in advance before or at the start of the pickup operation of suction nozzle 45, and stops ejector 62 when the pressure value of the negative pressure air is equal to the predetermined value or closer to the vacuum value than the predetermined value (normal state) at the end of or after the pickup operation. Further, negative pressure supply control section 72 continues the operation of ejector 62 until the mounting operation of suction nozzle 45 when the pressure value of the negative pressure air is closer to the atmospheric pressure value than the predetermined value at the end of or after the pickup operation (decreasing tendency state).

That is, since it is not possible to determine in advance whether the operation of ejector 62 is necessary before or at the start of the pickup operation of suction nozzle 45, negative pressure supply control section 72 operates ejector 62 in advance when necessary. Then, negative pressure supply control section 72 stops ejector 62 at the end of or after the pickup operation in a normal state, and continues the operation of ejector 62 in a decreasing tendency state. Thus, the influence of the response delay time DT of ejector 62 can be avoided. However, even when the normal state is determined as a result, ejector 62 is operated for a short time.

In addition, negative pressure detection section 71 may detect a negative pressure decreased state in which the pressure value of the negative pressure air exceeds the threshold pressure value and approaches the atmospheric pressure value while multiple suction nozzles 45 sequentially perform the pickup operation. In this case, negative pressure supply control section 72 notifies mounting control section 9 of the negative pressure decreased state. Mounting control section 9 that has received the notification of the negative pressure decreased state stops the pickup operation and shifts to the mounting operation. Accordingly, the pickup operation of one of suction nozzles 45 is omitted, mounting head 43 immediately moves above board K, and a smaller number of suction nozzles 45 than in the normal state perform the mounting operation. The control of negative pressure supply control section 72 will also be described in the following description of the operation.

### 4. Operation of Pickup and Mounting Cycle Using Suction Nozzle 45

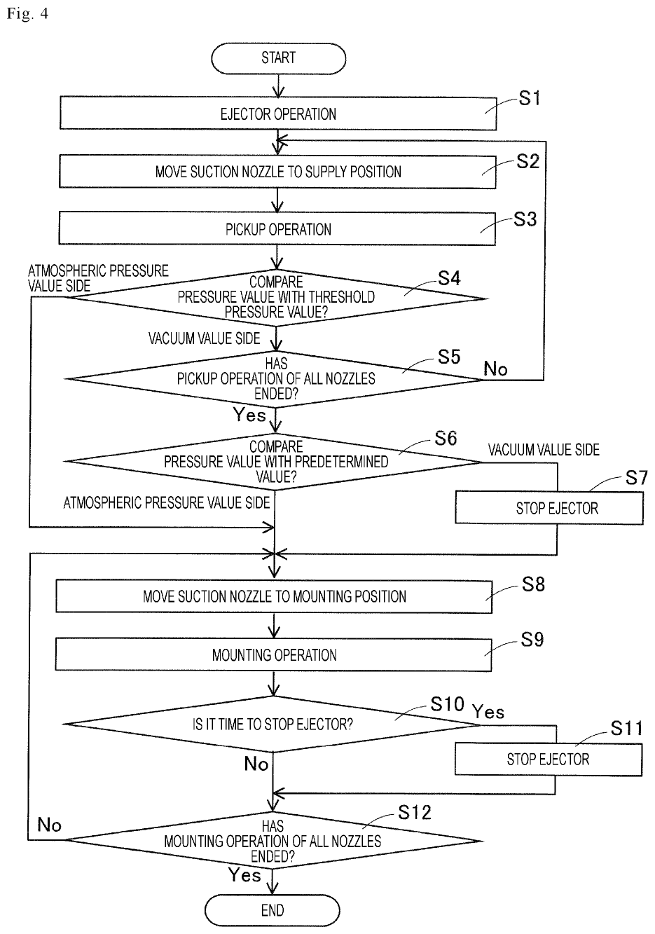

Next, an operation when component mounting device 1 performs the pickup and mounting cycle using suction nozzle 45 will be described with reference to FIGS. 4 to 6. The operation flow illustrated in FIG. 4 is mainly advanced by cooperative control of negative pressure supply control section 72 and mounting control section 9. In an initial state before the pickup and mounting cycle is started, nozzle side air flow path 54 of valve device 53 communicates with atmospheric air flow path 55, and suction nozzle 45 is in an atmosphere open state. In addition, due to the operation of first negative pressure supply section 61, the negative pressure air in negative pressure air flow path 51 has a pressure value close to the vacuum value. Further, positive pressure valve 85 is in an open state, and the positive pressure air in positive pressure air flow path 52 has a specified positive pressure value.

In the operation flow illustrated in FIG. 4, there may occur a first case where each of multiple suction nozzles 45 has successfully picked up a component, a second case where suction nozzle 45 has not successfully picked up a component and negative pressure air leaks, and a third case where the negative pressure air leaks much. In general, the occurrence frequency of the first case is the highest, the occurrence frequency of the second case is low, and the occurrence frequency of the third case is very rare. First, the time chart of FIG. 5 in the first case will be described. In FIG. 5, the band graph of the operation category of the suction nozzle represents distinction among pickup time band TW1, movement time band TW2, and mounting time band TW3.

Pickup time band TW1 is a time band from time t1 to time t4 in which multiple suction nozzles 45 sequentially perform the pickup operation at supply position 32. Time t1 is a time at which first suction nozzle 45 among multiple suction nozzles 45 starts the pickup operation at supply position 32, and time t4 is a time at which last suction nozzle 45 among multiple suction nozzles 45 ends the pickup operation. Movement time band TW2 is a time band from time t4 to time t7 in which mounting head 43 holding multiple suction nozzles 45 moves from component supply device 3 above board K via component recognition camera 49. Mounting time band TW3 is a time band from time t7 to time t11 in which multiple suction nozzles 45 sequentially perform the mounting operation at the mounting positions on board K. Time t7 is a time at which first suction nozzle 45 among multiple suction nozzles 45 starts the mounting operation at the mounting position, and time t11 is a time at which last suction nozzle 45 among multiple suction nozzles 45 ends the pickup operation.

Further, the band graph of the required time band represents a time band in which negative pressure air supplied from ejector 62 is required. Start time t3 of the required time band is set to be later than start time t1 of pickup time band TW1. This is because there is no problem without ejector 62 even if the leakage of the negative pressure air occurs in all suction nozzles 45 that perform the pickup operation from time t1 to time t3. Further, when the leakage of the negative pressure air also occurs in suction nozzle 45 performing the pickup operation after time t3, the negative pressure decreased state occurs, and thus the operation of ejector 62 is required. That is, if the supply of the negative pressure air by the operation of ejector 62 is started at time t3, the subsequent pressure value is recovered to the normal state, and the decreasing tendency state is maintained even in a bad state, and the negative pressure decreased state does not occur.

Meanwhile, end time t9 of the required time band is set earlier than end time t11 of mounting time band TW3. This is because, in suction nozzle 45 that has ended the mounting operation by time t9, negative pressure air flow path 51 is closed by valve device 53 and no leakage occurs, and even if leakage of the negative pressure occurs in remaining suction nozzles 45 that perform the mounting operation, there is no problem without ejector 62. That is, even when the supply of the negative pressure air of ejector 62 ends at time 19, the mounting operation of remaining suction nozzles 45 ends without trouble before the pressure value changes to the threshold pressure value.

The band graph of operation time represents a time band from time t1 to time t5 in which ejector 62 operates. The band graph of the positive pressure consumption represents a time band from time t2 at which the positive pressure air is discharged (consumed) from positive pressure discharge section 622 of ejector 62 to time t6. The time band of the positive pressure consumption has a slight response delay time with respect to the operation time. The band graph of the negative pressure effect represents a net time band in which the negative pressure air is supplied to suction nozzle 45, that is, a time band from time t3 to time t8. The time band of the negative pressure effect has response delay time DT (=t3−t1≈t8−t5) with respect to the operation time.

Returning to the operation flow of FIG. 4, the first case will be described. In step S1, negative pressure supply control section 72 opens opening/closing valve 63 and starts the operation of ejector 62 (time t1 in FIG. 5). Step S1 is processing of operating ejector 62 in advance in preparation for a case where the operation of ejector 62 is necessary. Accordingly, first negative pressure supply section 61 and ejector 62 supply the negative pressure air in parallel. The operation start time of ejector 62 is preferably set to a time earlier than start time t3 of the required time band by response delay time DT. In the example of FIG. 5, the operation start time of ejector 62 accidentally coincides with start time t1 of pickup time band TW1, but may be set before time t1 or after t1.

In next step S2, mounting control section 9 moves suction nozzle 45 above supply position 32 of component supply device 3. At next step S3, mounting control section 9 lowers suction nozzle 45 toward supply position 32. Thus, valve device 53 is automatically operated. Then, suction nozzle 45 shifts from the atmosphere open state to the negative pressure state, and performs the pickup operation.

In next step S4, negative pressure supply control section 72 compares the pressure value detected by negative pressure detection section 71 with the threshold pressure value. In the first case, there is almost no leakage of the negative pressure air, and the detected pressure value is closer to the vacuum value than the threshold pressure value. Accordingly, the execution of the operation flow proceeds to step S5. In step S5, mounting control section 9 determines whether the pickup operation of all suction nozzles 45 has ended. If not, the execution of the operation flow returns to step S2 while focusing on next suction nozzle 45. Then, the repeated loop from step S2 to step S5 is repeated the number of times corresponding to the number of suction nozzles 45.

When the pickup operation of all suction nozzles 45 has ended by repeating the pickup operation (time t4), the execution of the operation flow proceeds from step S5 to step S6. In step S6, negative pressure supply control section 72 compares the pressure value detected by negative pressure detection section 71 with the predetermined value. In the first case, there is almost no leakage of the negative pressure air, and the detected pressure value is closer to the vacuum value than the predetermined value (normal state). Accordingly, the execution of the operation flow proceeds to step S7. In step S7, negative pressure supply control section 72 stops ejector 62 (time t5).

In next step S8, mounting control section 9 moves suction nozzle 45 above the mounting position of board K (time t7). In next step S9, mounting control section 9 lowers suction nozzle 45 toward the mounting position. Thus, valve device 53 is automatically operated. Then, suction nozzle 45 shifts from the negative pressure state to the positive pressure state and performs the mounting operation. Thereafter, valve device 53 is automatically operated by the lifting of suction nozzle 45, and suction nozzle 45 shifts from the positive pressure state to the atmosphere open state. Next step S10 is omitted because ejector 62 is already stopped in step S7, and the execution of the operation flow proceeds to step S12.

In step S12, mounting control section 9 determines whether the mounting operation of all suction nozzles 45 has ended. If not, the execution of the operation flow returns to step S8 while focusing on next suction nozzle 45. Then, the repeated loop from step S8 to step S12 is repeated the number of times corresponding to the number of suction nozzles 45. When the mounting operation of all suction nozzles 45 has ended by repeating the mounting operation (time t11), the pickup and mounting cycle ends. In the first case, first negative pressure supply section 61 and ejector 62 are operated in parallel, but the operation of ejector 62 is not necessary as a result.

Next, the second case where any one of multiple suction nozzles 45 cannot pick up a component successfully and negative pressure air leaks will be described with reference to FIGS. 4 and 6. In the second case, after the pickup operation according to the repeated loop from step S2 to step S5, negative pressure air leaks from at least one suction nozzle 45. Therefore, when negative pressure supply control section 72 performs the comparison in step S6, the detected pressure value becomes closer to the atmospheric pressure value than the predetermined value (decreasing tendency state). Then, the execution of the operation flow proceeds to step S8 without going through step S7.

As a result, as illustrated in FIG. 6, ejector 62 also operates after time t5. Accordingly, as compared with the first case, the time during which first negative pressure supply section 61 and ejector 62 are operated in parallel is secured to be longer, the decrease in the pressure value of the negative pressure air (the increase in the absolute pressure) is suppressed, and the pressure value is recovered to the normal state in many cases. That is, in the second case, a remarkable effect is obtained by operating first negative pressure supply section 61 and ejector 62 in parallel.

Further, step S10 is executed every time the mounting operation is performed by the repeated loop from step S8 to step S12. In step S10, negative pressure supply control section 72 determines whether it is time to stop ejector 62. Then, in step S11 when it is time to stop, negative pressure supply control section 72 stops ejector 62 (time t9 in FIG. 6).

In FIG. 6, the time to stop ejector 62 (end time 19 of the operation time) is set to coincide with end time t9 of the required time band. Thus, the time band of positive pressure consumption in ejector 62 is extended until time t10. Further, end time t11 of the negative pressure effect is delayed from end time t9 by approximately response delay time DT, and approximately coincides with end time t11 of mounting time band TW3. Accordingly, ejector 62 produces a negative pressure effect through mounting time band TW3. As a result, in the second case as well, a decrease in the negative pressure in suction nozzle 45 is suppressed, the component is prevented from falling, and the mounting operation is stabilized. The time to stop ejector 62 (end time t9 of the operation time) can be changed.

Next, the third case where there is a large amount of leakage of negative pressure air will be described. In the third case, a large amount of negative pressure air leaks from at least one suction nozzle 45 during the pickup operation according to the repeated loop from step S2 to step S5. When negative pressure supply control section 72 performs the comparison in step S4, the detected pressure value is closer to the atmospheric pressure value than the threshold pressure value (negative pressure decreased state). Negative pressure supply control section 72 notifies mounting control section 9 of the negative pressure decreased state. Mounting control section 9 that has received the notification of the negative pressure decreased state stops the pickup operation and shifts to the mounting operation. In other words, the execution of the operation flow immediately proceeds from step S4 to step S8.

As a result, the pickup operation of some of suction nozzles 45 is omitted, mounting head 43 immediately moves to board K, and a smaller number of suction nozzles 45 than in the normal state perform the mounting operation. Accordingly, the mounting operation can end in a short time before the pressure value exceeds the limit value and approaches the atmospheric pressure value, and the component does not fall.

In component mounting device 1 of the first embodiment, first negative pressure supply section 61 operates at least throughout the time band from when suction nozzle 45 starts the pickup operation to when suction nozzle 45 starts the mounting operation, and maintains the inside of suction nozzle 45 at a negative pressure. Here, when suction nozzle 45 cannot pick up a component, or when the posture of a component or the state of the surface to be picked up is not good even if suction nozzle 45 can pick up the component, the negative pressure air leaks, and the negative pressure decreases in suction nozzle 45. In addition, in a configuration in which multiple suction nozzles are provided, when a decrease in the negative pressure occurs in suction nozzle 45, the decrease in the negative pressure affects other suction nozzles 45 in communication. When the negative pressure decreases in this manner, negative pressure detection section 71 detects the decrease in the negative pressure, and negative pressure supply control section 72 operates ejector 62, and therefore a decrease in the negative pressure inside suction nozzle 45 can be suppressed by operating first negative pressure supply section 61 and ejector 62 in parallel.

In addition, since the negative pressure in suction nozzle 45 can be favorably maintained and the component holding force can be increased, the moving speed of suction nozzle 45 can be increased as compared with the related art. In addition, since the component holding force is increased, suction nozzle 45 can perform pickup, conveyance, and mounting of a component heavier than in the related art.

### 5. Modification (Modification of Operation of Ejector 62)

In the first embodiment, in consideration of response delay time DT of ejector 62, negative pressure supply control section 72 operates ejector 62 in advance regardless of necessity. However, the operation of ejector 62 is not necessary as a result in the first case where the occurrence frequency is high, and the positive pressure air is wasted. Therefore, in a modification, the overall configuration of component mounting device 1 (see FIG. 1) and the configuration of air supply system 5 (see FIG. 2) are not changed, and the operation of ejector 62 under the control of negative pressure supply control section 72 is modified to eliminate the waste of the positive pressure air.

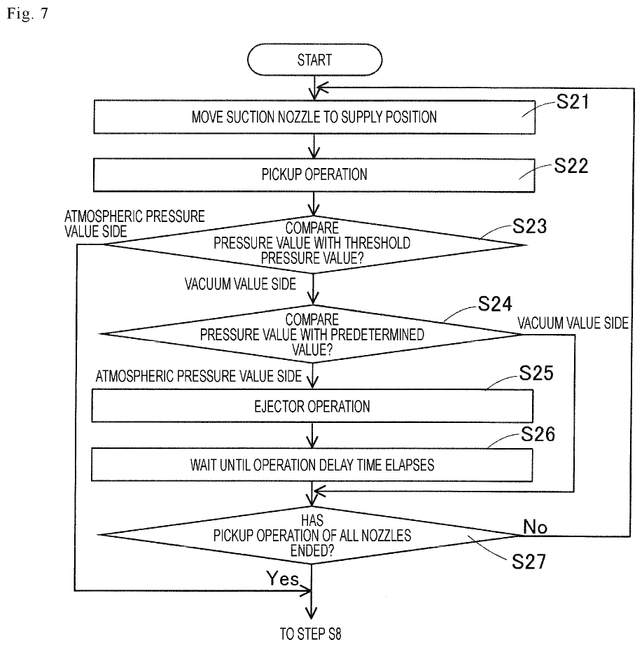

In the modification, the operation flow of the pickup operation illustrated in FIG. 7 is advanced mainly by the cooperative control of negative pressure supply control section 72 and mounting control section 9. Specifically, ejector 62 does not operate at the start of the pickup and mounting cycle. Then, in step S21, mounting control section 9 moves suction nozzle 45 above supply position 32 of component supply device 3. In next step S22, mounting control section 9 lowers the suction nozzle 45 toward supply position 32. Accordingly, valve device 53 is automatically operated, and suction nozzle 45 shifts from the atmosphere open state to the negative pressure state to perform the pickup operation.

In next step S23, negative pressure supply control section 72 compares the pressure value detected by negative pressure detection section 71 with the threshold pressure value. In the third case described above, in other words, when the pressure value is closer to the atmospheric pressure value than the threshold pressure value (negative pressure decreased state), the execution of the operation flow proceeds from step S23 to step S8 of FIG. 4 immediately. In this case, ejector 62 is preferably operated. In the above-described first and second cases, the pressure value is closer to the vacuum value than the threshold pressure value, and the execution of the operation flow proceeds to step S24.

In step S24, negative pressure supply control section 72 compares the pressure value detected by negative pressure detection section 71 with a predetermined value. The predetermined value used in the modification may be different from the predetermined value in the first embodiment. That is, while the predetermined value in the first embodiment corresponds to the pressure value at which ejector 62 is not necessary, the predetermined value in the modification corresponds to the pressure value at which ejector 62 is necessary, and thus is preferably set to be higher than that in the first embodiment. In the first case, there is almost no leakage of the negative pressure air, and the detected pressure value is closer to the vacuum value than the predetermined value. Accordingly, the execution of the operation flow proceeds to step S27. In the second case, the detected pressure value becomes closer to the atmospheric pressure value side than the predetermined value (decreasing tendency state), and the execution of the operation flow proceeds to step S25.

In step S25, negative pressure supply control section 72 operates ejector 62. In next step S26, mounting control section 9 waits until response delay time DT elapses without advancing the pickup operation of next suction nozzle 45. The waiting time in step S26 may be reduced or omitted by providing ejector 62 at a position close to suction nozzle 45 to reduce response delay time DT. By operating first negative pressure supply section 61 and ejector 62 in parallel, the pressure value of the negative pressure air recovers to the normal state. After step S26 ends, the execution of the operation flow proceeds to step S27.

In step S27, mounting control section 9 determines whether the pickup operation of all suction nozzles 45 has ended. If not, the execution of the operation flow is returned to step S21 while focusing on next suction nozzle 45. Then, the repeated loop from step S21 to step S27 is repeated the number of times corresponding to the number of suction nozzles 45. When the pickup operation of all suction nozzles 45 has ended by repeating the pickup operation, the execution of the operation flow proceeds from step S27 to step S8 of FIG. 4 and shifts to the mounting operation.

In the modification, ejector 62 does not operate in the first case, and ejector 62 operates in the second case and the third case. Thus, ejector 62 is operated only when necessary, and waste of the positive pressure air can be eliminated.

### 6. Second Embodiment

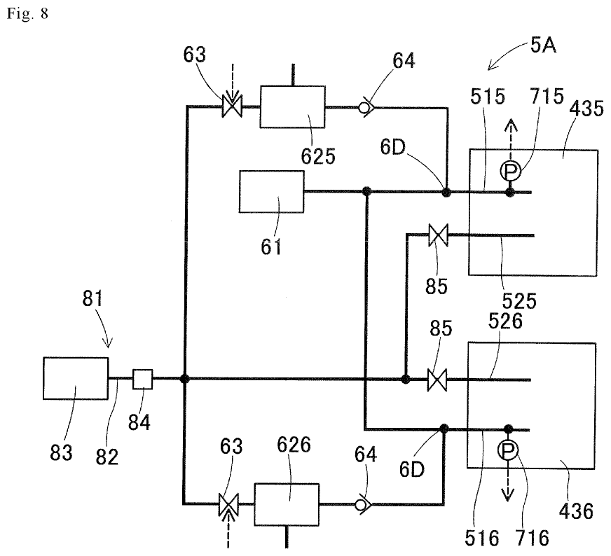

Next, air supply system 5A according to a second embodiment will be described with reference to FIG. 8. In the second embodiment, component mounting device 1 has a dual-head structure including two mounting heads (435, 436). To correspond to the two mounting heads (435, 436), air supply system 5A includes two sets of negative pressure air flow paths (515, 516), two sets of positive pressure air flow paths (525, 526), two sets of ejectors (625, 626) corresponding to first negative pressure supply section 61 and the second negative pressure supply section, two negative pressure detection sections (715, 716), negative pressure supply control section 72, and positive pressure supply section 81. In FIG. 8, the configuration of air supply system 5A provided inside each of the two mounting heads (435, 436) is the same as that in FIG. 2.

A first end side of first negative pressure air flow path 515 branches into two systems at branch position 6D, and communicates with first negative pressure supply section 61 and ejector 625 in parallel. A second end side of negative pressure air flow path 515 communicates with mounting head 435 and branches into the number of systems equal to the number of suction nozzles 45, and each of the systems communicates with valve device 53.

Similarly to first negative pressure air flow path 515, a first end side of second negative pressure air flow path 516 branches into two systems at branch position 6D and communicates with first negative pressure supply section 61 and ejector 626 in parallel. A second end side of negative pressure air flow path 516 communicates with mounting head 436 and branches into the number of systems equal to the number of suction nozzles 45, and each of the systems communicates with valve device 53. As illustrated, negative pressure air flow path 515 and negative pressure air flow path 516 merge before first negative pressure supply section 61. That is, first negative pressure supply section 61 is provided to two mounting heads (435, 436) in common. Meanwhile, ejector (625, 626) is individually provided for the two mounting heads (435, 436).

A first end side of first positive pressure air flow path 525 communicates with positive pressure supply section 81 via positive pressure valve 85. A second end side of positive pressure air flow path 525 communicates with mounting head 435 and branches to the number of systems equal to the number of suction nozzles 45, and each of the systems communicates with valve device 53.

Similarly to first positive pressure air flow path 525, a first end side of second positive pressure air flow path 526 communicates with positive pressure supply section 81 via positive pressure valve 85. A second end side of the positive pressure air flow path 526 communicates with mounting head 436 and branches to the number of systems equal to the number of the suction nozzles 45, and each of the systems communicates with valve device 53. As illustrated in the drawing, positive pressure air flow path 525 and positive pressure air flow path 526 merge before positive pressure supply section 81. That is, positive pressure supply section 81 is provided to two mounting heads (435, 436) in common.

The discharge side of regulator valve 84 branches off from positive pressure supply section 81, and communicates with each of opening/closing valves 63 of two sets of ejectors (625, 626). Positive pressure supply section 81 contributes to generation of negative pressure air, and serves as a part of the two second negative pressure supply sections. Further, the discharge side of regulator valve 84 branches off from positive pressure supply section 81, communicates with two positive pressure valves 85, and supplies the positive pressure air to suction nozzles 45 of the two mounting heads (435, 436) via positive pressure air flow paths (525, 526).

First negative pressure detection section 715 is provided to communicate with negative pressure air flow path 515 in mounting head 435. Second negative pressure detection section 716 is provided to communicate with negative pressure air flow path 516 in mounting head 436. That is, negative pressure detection sections (715, 716) are individually provided for the two mounting heads (435, 436). Negative pressure supply control section 72 (not illustrated in FIG. 8) controls the operation of ejector 625 based on the pressure value detected by negative pressure detection section 715. Negative pressure supply control section 72 controls the operation of ejector 626 based on the pressure value detected by negative pressure detection section 716.

As illustrated in FIG. 8, air can flow in two directions between negative pressure air flow path 515 and negative pressure air flow path 516. However, the pressure values detected by the two negative pressure detection sections (715, 716) disposed apart from each other may be different due to the restriction of the passage cross-sectional area or the like. In other words, suction nozzle 45 of mounting head 435 and suction nozzle 45 of mounting head 436 may have different pressure values. Therefore, negative pressure supply control section 72 performs individual control for each of the mounting heads (435, 436). In the second embodiment, the number of the mounting heads (435, 436) is different from that in the first embodiment, but the same operation as in the first embodiment can be performed, and the same effects as in the first embodiment are produced.

### 7. Third Embodiment

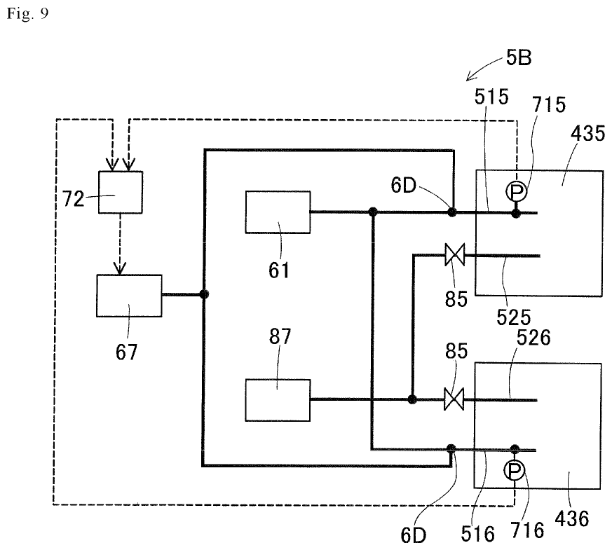

Next, air supply system 5B according to a third embodiment will be described with reference to FIG. 9. In the third embodiment, component mounting device 1 has a dual-head structure as in the second embodiment. To correspond to the two mounting heads (435, 436), air supply system 5A includes two sets of negative pressure air flow paths (515, 516), two sets of positive pressure air flow paths (525, 526), first negative pressure supply section 61, second negative pressure supply section 67, two negative pressure detection sections (715, 716), negative pressure supply control section 72, positive pressure supply section 87, and the like. In FIG. 9, the configuration of air supply system 5B provided inside each of the two mounting heads (435, 436) is the same as that in FIG. 2.

A first end side of first negative pressure air flow path 515 branches into two systems at branch position 6D, and communicates with first negative pressure supply section 61 and second negative pressure supply section 67 in parallel. A second end side of negative pressure air flow path 515 communicates with mounting head 435 and branches into the number of systems equal to the number of suction nozzles 45, and each of the systems communicates with valve device 53.

Similarly to first negative pressure air flow path 515, a first end side of second negative pressure air flow path 516 branches into two systems at branch position 6D, and communicates with first negative pressure supply section 61 and second negative pressure supply section 67 in parallel. A second end side of negative pressure air flow path 516 communicates with mounting head 436 and branches into the number of systems equal to the number of suction nozzles 45, and each of the systems communicates with valve device 53. As illustrated, negative pressure air flow path 515 and negative pressure air flow path 516 merge before first negative pressure supply section 61. Further, negative pressure air flow path 515 and negative pressure air flow path 516 merge before second negative pressure supply section 67.

Second negative pressure supply section 67 is provided to the two mounting heads (435, 436) in common. Second negative pressure supply section 67 is implemented by, for example, an air pump (vacuum pump) provided in base 10. Second negative pressure supply section 67 implemented by the air pump has response delay time DT similar to that of ejector 62.

A first end side of first positive pressure air flow path 525 communicates with positive pressure supply section 87 via positive pressure valve 85. A second end side of positive pressure air flow path 525 communicates with mounting head 435 and branches to the number of systems equal to the number of suction nozzles 45, and each of the systems communicates with valve device 53.

Similarly to first positive pressure air flow path 525, a first end side of second positive pressure air flow path 526 communicates with positive pressure supply section 87 via positive pressure valve 85. A second end side of the positive pressure air flow path 526 communicates with mounting head 436 and branches to the number of systems equal to the number of the suction nozzles 45, and each of the systems communicates with valve device 53. As illustrated in the drawing, positive pressure air flow path 525 and positive pressure air flow path 526 merge before positive pressure supply section 87.

Positive pressure supply section 87 is provided to the two mounting heads (435, 436) in common. Positive pressure supply section 87 is disposed on base 10. Positive pressure supply section 87 includes, for example, a compressor and an accumulator tank in which positive pressure air is accumulated by the compressor.

First negative pressure detection section 715 is provided to communicate with negative pressure air flow path 515 in mounting head 435. Second negative pressure detection section 716 is provided to communicate with negative pressure air flow path 516 in mounting head 436. That is, negative pressure detection sections (715, 716) are individually provided for the two mounting heads (435, 436). Negative pressure supply control section 72 controls the operation of second negative pressure supply section 67 based on the pressure value on the inferior side (the side closer to the atmospheric pressure value) of the two pressure values detected by two negative pressure detection sections 715.

As illustrated in FIG. 9, air may flow in two directions between negative pressure air flow path 515 and negative pressure air flow path 516, but the pressure values detected by the two negative pressure detection sections (715, 716) may be different due to the restriction of the passage cross-sectional area or the like. Therefore, when a decreasing tendency of the negative pressure is detected in at least one of the two pressure values, negative pressure supply control section 72 operates second negative pressure supply section 67 to supply the negative pressure air to negative pressure air flow paths (515, 516) of the two systems, thereby suppressing the decrease of the negative pressure. In the third embodiment, the number of the mounting heads (435, 436) and the structures of second negative pressure supply section 67 and positive pressure supply section 87 are different from those of the first embodiment, but the same operation as in the first embodiment can be performed, and the same effects as in the first embodiment are produced.

### 8. Application and Modification of Embodiment

The modification of the first embodiment can be applied to the second embodiment and the third embodiment. Further, at least one of first negative pressure supply section 61, ejectors (62, 625, 626), second negative pressure supply section 67, and positive pressure supply section 81 may be disposed inside the mounting heads (43, 435, 436) or rotary tool 44. Further, in the air supply systems (5, 5A, 5B), it is possible to change the communicating system configuration and change the type, structure, number, arrangement, and the like of the valves. Various other applications and modifications can be made for the first to third embodiments.

### REFERENCE SIGNS LIST

1: component mounting device, 10: base, 2: board conveyance device, 3: component supply device, 4: component transfer device, 43, 435, 436: mounting head, 44: rotary tool, 45: suction nozzle, 5, 5A, 5B: air supply system, 51, 515, 516: negative pressure air flow path, 52, 525, 526: positive pressure air flow path, 53: valve device, 54: nozzle side air flow path, 55: atmospheric air flow path, 61: first negative pressure supply section, 62, 625, 626: ejector, 63: opening/closing valve, 64: check valve, 67: second negative pressure supply section, 71, 715, 716: negative pressure detection section, 72: negative pressure supply control section, 81, 87: positive pressure supply section, 9: mounting control section, DT: response delay time

1. A component mounting device comprising:
a suction nozzle configured to be supplied with negative pressure air to perform pickup operation of picking up a component, and configured to be blocked from the negative pressure air to perform mounting operation of mounting the component on a board;
a first negative pressure supply section configured to supply the negative pressure air to the suction nozzle throughout a time band from when the suction nozzle starts the pickup operation to when the suction nozzle starts the mounting operation;
a second negative pressure supply section configured to supply the negative pressure air to the suction nozzle;
a negative pressure detection section configured to directly or indirectly detect a pressure value of the negative pressure air supplied to the suction nozzle; and
a negative pressure supply control section configured to operate the second negative pressure supply section when the detected pressure value of the negative pressure air is closer to an atmospheric pressure value than a predetermined value set between the atmospheric pressure value and a vacuum value.

2. The component mounting device according to claim 1, wherein
the negative pressure supply control section
operates the second negative pressure supply section in advance before or at the start of the pickup operation of the suction nozzle, and
when the pressure value of the negative pressure air is equal to the predetermined value or is closer to the vacuum value than the predetermined value, stops the second negative pressure supply section, and when the pressure value of the negative pressure air is closer to the atmospheric pressure value than the predetermined value, continues to operate the second negative pressure supply section until the mounting operation of the suction nozzle at the end of or after the pickup operation.

3. The component mounting device according to claim 1, wherein
when the pressure value of the negative pressure air exceeds the predetermined value and approaches the atmospheric pressure value during the pickup operation of the suction nozzle, the negative pressure supply control section operates the second negative pressure supply section, and further continues to operate the second negative pressure supply section until the mounting operation of the suction nozzle.

4. The component mounting device according to claim 2, wherein
the predetermined value is set based on a condition that the component does not fall when the suction nozzle moves while picking up the component.

5. The component mounting device according to claim 1, further comprising:
a mounting head including multiple suction nozzles.

6. The component mounting device according to claim 2, further comprising:
a mounting head including the multiple suction nozzles; and
a mounting control section configured to control the multiple suction nozzles and the mounting head, wherein
when the negative pressure detection section detects a negative pressure decreased state in which the pressure value of the negative pressure air exceeds a threshold pressure value set between the atmospheric pressure value and the predetermined value and approaches the atmospheric pressure value while the multiple suction nozzles are sequentially performing the pickup operation, the mounting control section stops the pickup operation and shifts to the mounting operation.

7. The component mounting device according to claim 5, further comprising:
multiple mounting heads, wherein
the first negative pressure supply section is provided to the multiple mounting heads in common, and
the second negative pressure supply section and the negative pressure detection section are individually provided to the multiple mounting heads.

8. The component mounting device according to claim 1, wherein
the negative pressure supply control section performs control in consideration of a response delay time required until the negative pressure air is supplied to the suction nozzle after the second negative pressure supply section starts to operate.

9. The component mounting device according to claim 1, wherein
the second negative pressure supply section includes an air pump, or an ejector to which positive pressure air is supplied to generate the negative pressure air.

10. The component mounting device according to claim 9, wherein
the second negative pressure supply section includes the ejector, and a positive pressure supply section configured to supply the positive pressure air to the ejector and the suction nozzle.

11. The component mounting device according to claim 1, wherein
the first negative pressure supply section continues to operate when the component mounting device is in operation.

12. The component mounting device according to claim 1, wherein
the first negative pressure supply section includes a negative pressure source disposed inside the component mounting device or a negative pressure air supply path configured to supply the negative pressure air into the device from a negative pressure source disposed outside the component mounting device.
